(19) United States
(12) Patent Application Publication
(10) Pub. No.: US 2026/0260687 A1
(43) Pub. Date: Sep. 3, 2026

(54) STATIC RANDOM-ACCESS MEMORY (SRAM) ARCHITECTURE USING WORD LINE (WL) CUT BIT CELL

(71) Applicant: QUALCOMM Incorporated, San Diego, CA (US)

(72) Inventors: Naveen Kumar BASKARAN, Bangalore (IN); Kamlesh KUMAR, Bangalore (IN); Seohee KIM, San Diego, CA (US); Yi-Ju CHEN, Toufen City (TW); Channappa DESAI, Haveri (IN); Anne SRIKANTH, Bangalore (IN); Sung SON, San Jose, CA (US); Pradeep Jayadev KODLIPET, Bangalore (IN)

(21) Appl. No.: 19/067,184

(22) Filed: Feb. 28, 2025

(51) Int. Cl. G11C 11/412; G11C 5/14; G11C 11/418; G11C 11/419

(52) U.S. Cl. CPC G11C 11/412; G11C 5/147; G11C 5/148; G11C 11/418; G11C 11/419

(57) ABSTRACT

A system includes a first static-random access memory (SRAM) bit cell coupled to a first word line, and a first word line (WL) cut bit cell. The first WL cut bit cell includes a first inverter, a second inverter cross-coupled with the first inverter, a first pass transistor coupled between an output of the first inverter and a low rail, wherein a gate of the first pass transistor is coupled to the first word line, and a second pass transistor coupled between an output of the second inverter and the low rail, wherein a gate of the second pass transistor is tied low.

### BACKGROUND

### Field

Aspects of the present disclosure relate generally to memory, and more particularly, to static random-access memory (SRAM).

### Background

A chip (e.g., system on a chip) may include on-chip memory for storing data on the chip. The on-chip memory may include static random-access memory (SRAM) memory including an array of SRAM bit cells.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a first static-random access memory (SRAM) bit cell coupled to a first word line, and a first word line (WL) cut bit cell. The first WL cut bit cell includes a first inverter, a second inverter cross-coupled with the first inverter, a first pass transistor coupled between an output of the first inverter and a low rail, wherein a gate of the first pass transistor is coupled to the first word line, and a second pass transistor coupled between an output of the second inverter and the low rail, wherein a gate of the second pass transistor is tied low.

A second aspect relates to a system. The system includes a first static-random access memory (SRAM) bit cell coupled to a first word line, a second SRAM bit cell coupled to a second word line, and a first word line (WL) cut bit cell. The first WL cut bit cell includes a first inverter, a second inverter cross-coupled with the first inverter, a first pass transistor coupled between an output of the first inverter and a low rail, wherein a gate of the first pass transistor is coupled to the first word line, and a second pass transistor coupled between an output of the second inverter and the low rail, wherein a gate of the second pass transistor is coupled to the second word line.

A third aspect relates to a system. The system includes first static-random access memory (SRAM) bit cells arranged in a first row, a first word line (WL) cut bit cell in the first row, and a first word line extending over the first SRAM bit cells, wherein the first word line is coupled to each of the first SRAM bit cells, and the first word line is cut above the first WL cut bit cell. The system also includes second SRAM bit cells arranged in a second row, a second WL cut bit cell in the second row, and a second word line extending over the second SRAM bit cells, wherein the second word line is coupled to each of the second SRAM bit cells, and the second word line is cut above the second WL cut bit cell.

### BRIEF DESCRIPTION OF THE DRAWINGS

FIG. 1A shows an example of an SRAM bit cell according to certain aspects of the present disclosure.

FIG. 1B shows an exemplary implementation of inverters in the SRAM bit cell according to certain aspects of the present disclosure.

FIG. 2 shows an example of read circuitry for reading a bit from the SRAM bit cell according to certain aspects of the present disclosure.

FIG. 3A shows an example of a memory array including SRAM bit cells according to certain aspects of the present disclosure.

FIG. 3B shows an example of read circuitry and a row decoder coupled to the memory array of FIG. 3A according to certain aspects of the present disclosure.

FIG. 4 shows an example of a system configured to selectively place a memory array in different power modes according to certain aspects of the present disclosure.

FIG. 5 shows an example of a word line (WL) cut bit cell according to certain aspects of the present disclosure.

FIG. 6A shows a top view of a layout of a word line according to certain aspects of the present disclosure.

FIG. 6B shows an example in which the word line of FIG. 6A is cut into a first portion and a second portion according to certain aspects of the present disclosure.

FIG. 7 shows an example in which the WL cut bit cell is coupled to a tie-low cell according to certain aspects of the present disclosure.

FIG. 8 shows an example in which the WL cut bit cell is coupled to a tied-off bit cell according to certain aspects of the present disclosure.

FIG. 9 shows an example of a memory array including SRAM bit cells and WL cut bit cells according to certain aspects of the present disclosure.

FIG. 10 shows another example of a memory array including SRAM bit cells and WL cut bit cells according to certain aspects of the present disclosure.

FIG. 11A shows a top view of a layout of word lines arranged in rows according to certain aspects of the present disclosure.

FIG. 11B shows an example in which the word lines of FIG. 11A are cut according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip (e.g., system on a chip) may include on-chip (i.e., on-die) memory for storing data on the chip. The on-chip memory may include static random-access memory (SRAM) memory including an array of SRAM bit cells. For example, the SRAM memory may be used in cache memory and/or registers to store data for one or more processors on the chip. A bit cell may also be referred to as a memory cell or another term.

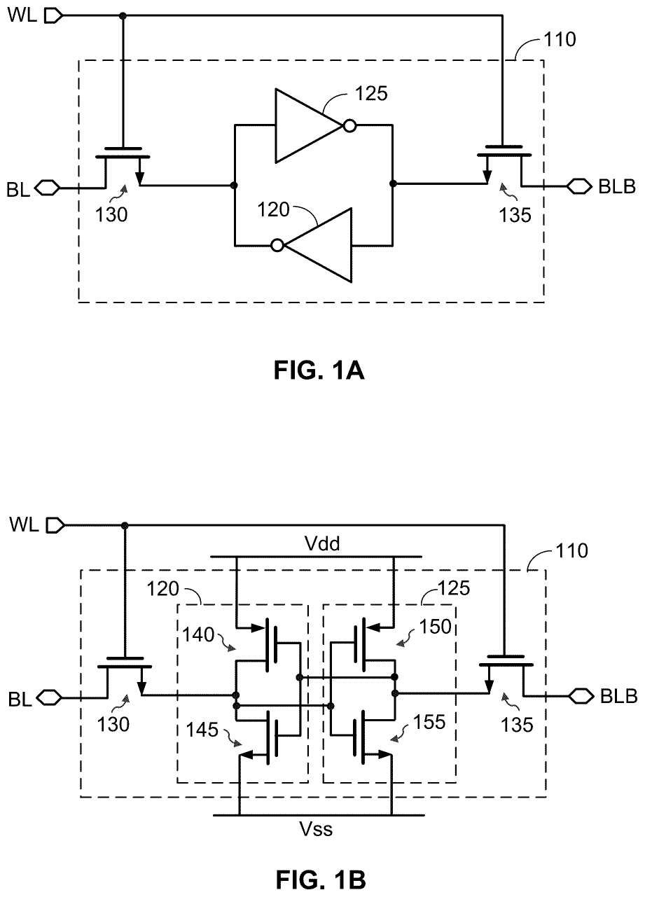

FIG. 1A shows a circuit diagram of an exemplary SRAM bit cell 110 for storing a bit. The SRAM memory may include many instances of the SRAM bit cell 110 arranged in an array, as discussed further below. In this example, the SRAM bit cell 110 includes a first inverter 120, a second inverter 125, a first pass transistor 130, and a second pass transistor 135. The second inverter 125 is cross coupled with the first inverter 120, in which the output of the first inverter 120 is coupled to the input of the second inverter 125 and the output of the second inverter 125 is coupled to the input of the first inverter 120.

The cross-coupled inverters 120 and 125 can be placed in one of two stable states during a write operation depending on the bit value to be stored in the SRAM bit cell 110. The two states includes a first state in which the output of the first inverter 120 is high and the output of the second inverter 125 is low, and a second state in which the output of the first inverter 120 is low and the output of the second inverter 125 is high. The first state may be used to store a bit value of one and the second state may be used to store a bit value of zero, or vice versa.

The first pass transistor 130 is coupled between the output of the first inverter 120 and a first bit line BL and the second pass transistor 135 is coupled between the output of the second inverter 125 and a second bit line BLB. The gates of the pass transistors 130 and 135 are coupled to a word line WL. A pass transistor may also be referred to as an access transistor or another term.

In order to write a bit into the SRAM bit cell 110 and/or read a bit from the SRAM bit cell 110, the pass transistors 130 and 135 are turned on by the word line WL to provide read/write circuity with access to the cross-coupled inverters 120 and 125 via the bit lines BL and BLB. The word line WL turns off the pass transistors 130 and 135 when the SRAM bit cell 110 is not being accessed for a write/read operation. In the example shown in FIG. 1A, each of the pass transistors 130 and 135 is implemented with a respective n-type field effect transistor (NFET). In this example, the word line WL is set high (e.g., supply voltage Vdd) to turn on the pass transistors 130 and 135, and the word line WL is set low (e.g., ground potential) to turn off the pass transistors 130 and 135. As used herein, setting the word line WL high means setting the word line WL to a voltage (e.g., supply voltage Vdd) that is sufficient to turn on the pass transistors coupled to the word line WL (i.e., a voltage exceeding the threshold voltage of the pass transistors).

FIG. 1B shows an exemplary implementation of the first inverter 120 and the second inverter 125. In this example, the first inverter 120 includes a p-type field effect transistor (PFET) 140 and an NFET 145 in which the source of the PFET 140 is coupled to a supply rail, the gates of the PFET 140 and the NFET 145 are coupled to the input of the first inverter 120, the drains of the PFET 140 and the NFET 145 are coupled to the output of the first inverter 120, and the source of the NFET 145 is coupled to a low rail (e.g., ground rail). The second inverter 125 includes a PFET 150 and an NFET 155 in which the source of the PFET 150 is coupled to the supply rail, the gates of the PFET 150 and the NFET 155 are coupled to the input of the second inverter 125, the drains of the PFET 150 and the NFET 155 are coupled to the output of the second inverter 125, and the source of the NFET 155 is coupled to the low rail (e.g., ground rail). As used herein, a “low rail” is a rail having a lower potential (e.g., ground potential) than the supply rail. For the example where the low rail is at ground potential, the low rail may be referred to as a ground rail.

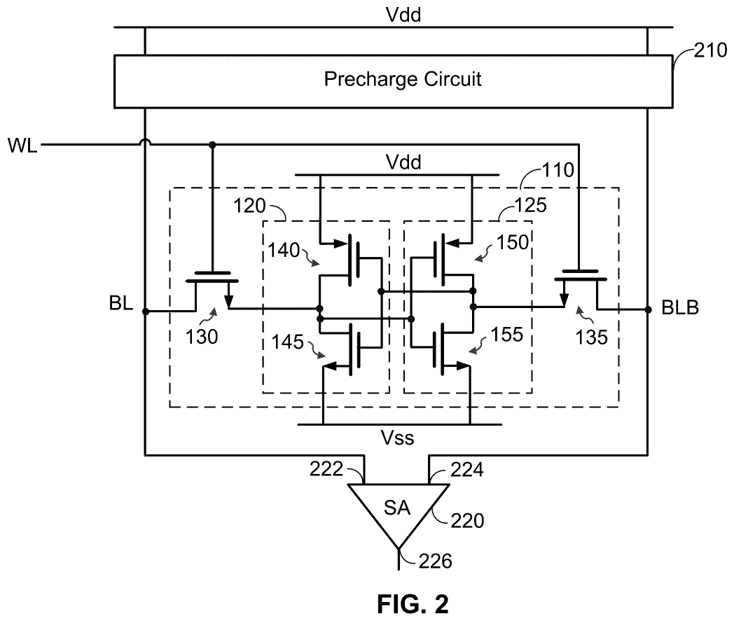

FIG. 2 shows an example of read circuitry for reading the bit stored in the SRAM bit cell 110. In this example, the read circuitry includes a precharge circuit 210 and a sense amplifier 220. The precharge circuit 210 is coupled between the first bit line BL and the supply rail and between the second bit line BLB and the supply rail. The sense amplifier 220 has a first input 222 coupled to the first bit line BL, a second input 224 coupled to the second bit line BLB, and an output 226.

To read the bit stored in the SRAM bit cell 110, the precharge circuit 210 precharges the bit lines BL and BLB to the supply voltage Vdd. After the bit lines BL and BLB are precharged to Vdd, the word line WL is set high to turn on the pass transistors 130 and 135. As a result, the output of the first inverter 120 is coupled to the first bit line BL through the first pass transistor 130 and the output of the second inverter 125 is coupled to the second bit line BLB through the second pass transistor 135.

The inverters 120 and 125 pull down the voltage of one of the bit lines BL and BLB depending on the bit value stored in the SRAM bit cell 110. This creates a voltage difference between the bit lines BL and BLB that can be sensed by the sense amplifier 220 to read the bit value stored in the SRAM bit cell 110. For example, if the SRAM bit cell 110 is in the first state (e.g., stored bit value is one), then the voltage of the second bit line BLB may be pulled down. If the SRAM bit cell 110 is in the second state (e.g., stored bit value is zero), then the voltage of the first bit line BL may be pulled down.

The sense amplifier 220 senses the voltage difference between the bit lines BL and BLB at the inputs 222 and 224 and outputs a read bit value of one or zero at the output 226 based on the voltage difference. For example, if the voltage of the first bit line BL is higher than the voltage of the second bit line BLB, then the sense amplifier 220 may output a bit value of one. If the voltage of the second bit line BLB is higher than the voltage of the first bit line BL, then the sense amplifier 220 may output a bit value of zero. However, it is to be appreciated that the sense amplifier 220 is not limited to this example. In certain aspects, the sense amplifier 220 may be configured to sense a small voltage difference between the bit lines BL and BLB to increase the speed of the read operation.

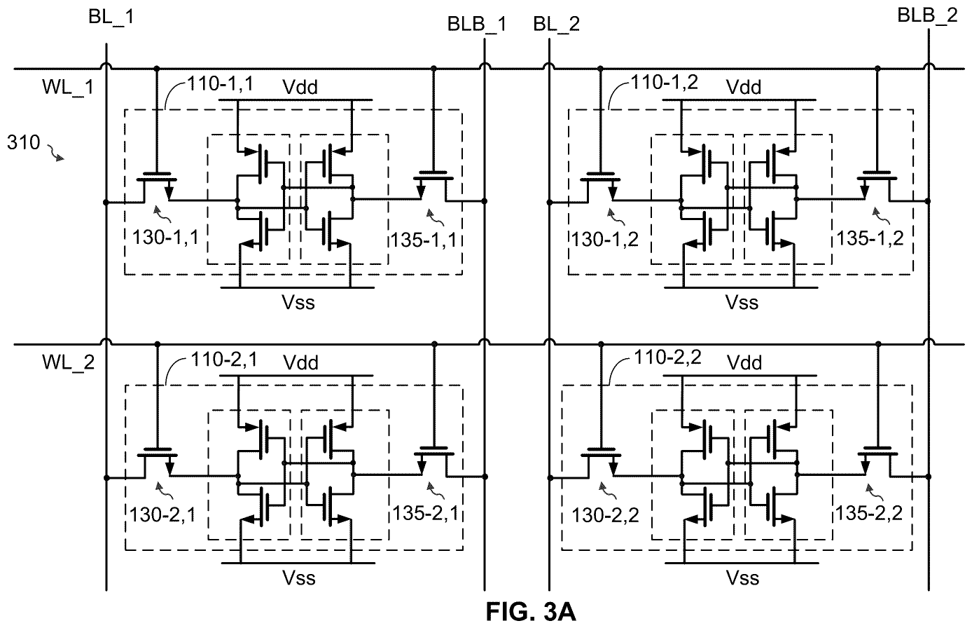

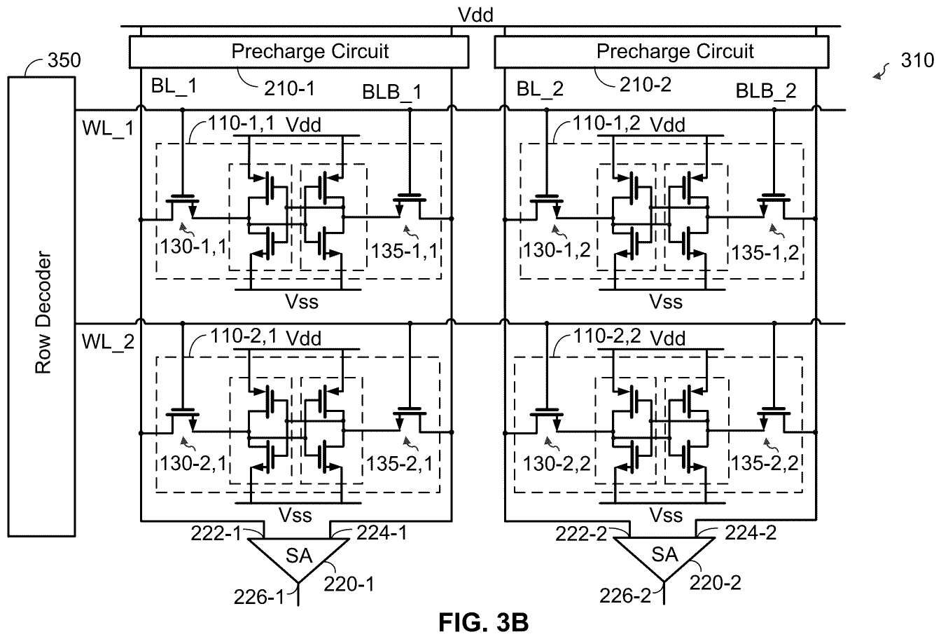

FIG. 3A shows an example of a memory array 310 including multiple SRAM bit cells 110-1,1 to 110-2,2 where each of the SRAM bit cells 110-1,1 to 110-2,2 is a separate instance (i.e., copy) of the SRAM bit cell 110. Thus, the description of the SRAM bit cell 110 given above applies to each of the SRAM bit cells 110-1,1 to 110-2,2. Note that FIG. 3A does not show the reference numbers for the inverters in each of the SRAM bit cells 110-1,1 to 110-2,2 to avoid clutter.

In this example, the multiple SRAM bit cells 110-1,1 to 110-2,2 are arranged in rows and columns. Although four SRAM bit cells 110-1,1 to 110-2,2 are shown in FIG. 3A for ease of illustration, it is to be appreciated that the memory array 310 may include a large number of SRAM bit cells. The memory array 310 includes multiple word lines where each of the word lines corresponds to a respective row in the memory array 310. The memory array 310 also includes multiple pairs of bit lines where each pair of bit lines corresponds to a respective column in the memory array 310. In the example shown in FIG. 3A, the word lines include a first word line WL_1 corresponding to a first row and a second word lines WL_2 corresponding to a second row. Also, the pairs of bit lines includes a first pair of bit lines BL_1 and BLB_1 corresponding to a first column and a second pair of bit lines BL_2 and BLB_2 corresponding to a second column. In FIG. 3A, the reference numbers for each of the SRAM bit cells 110-1,1 to 110-2,2 include a first numeral suffix referring to the corresponding row and a second numeral suffix referring to the corresponding column.

In this example, the SRAM memory may include read circuitry for reading the bits stored in the multiple SRAM bit cells 110-1,1 to 110-2,2. In this regard, FIG. 3B shows an example of read circuitry according to certain aspects. In this example, the read circuitry includes a first precharge circuit 210-1 and a first sense amplifier 220-1 configured to read bits from the SRAM bit cells 110-1,1 and 110-2,1 in the first column. The first precharge circuit 210-1 is coupled between the supply rail and the bit lines BL_1 and BLB_1, the first input 222-1 of the first sense amplifier 220-1 is coupled to the bit line BL_1, and the second input 224-1 of the first sense amplifier 220-1 is coupled to the bit line BLB_1. The read circuitry also includes a second precharge circuit 210-2 and a second sense amplifier 220-2 configured to read bits from the SRAM bit cells 110-1,2 and 110-2,2 in the second column. The second precharge circuit 210-2 is coupled between the supply rail and the bit lines BL_2 and BLB_2, the first input 222-2 of the second sense amplifier 220-2 is coupled to the bit line BL_2, and the second input 224-2 of the second sense amplifier 220-2 is coupled to the bit line BLB_2. Although FIG. 3B shows two SRAM bit cells in each column for ease of illustration, it is to be appreciated that the memory array 310 may include additional SRAM bit cells in each column located in different rows. Each of the precharge circuits 210-1 and 210-2 may be a respective instance of the precharge circuit 210 and each of the sense amplifiers 220-1 and 220-2 may be a respective instance of the sense amplifier 220.

FIG. 3B also shows an example of a row decoder 350 coupled to the word lines WL_1 and WL_2. The row decoder 350 is configured to select a row in the memory array 310 for a write/read operation. For example, to select the first row, the row decoder 350 may set the first word line WL_1 high to turn on the pass transistors in the SRAM bit cells 110-1,1 and 110-1,2 in the first row and set the second word line WL_2 low. To select the second row, the row decoder 350 may set the second word line WL_2 high to turn on the pass transistors in the SRAM bit cells 110-2,1 and 110-2,2 in the second row and set the first word line WL_1 low. In this example, the row decoder 350 selects one row at a time.

When a row is selected, the bit(s) stored in one or more of the SRAM bit cells in the row may be read using the read circuitry discussed above. For example, to read the SRAM bit cells 110-1,1 and 110-1,2 in the first row, the row decoder 350 selects the first row. The precharge circuits 210-1 to 210-2 precharge the bits lines BL_1, BLB_1, BL_2, and BLB_2 to the supply voltage. After precharge, the first sense amplifier 220-1 reads the bit stored in the SRAM bit cell 110-1,1 by sensing the voltage difference between the bit lines BL_1 and BLB_1, and the second sense amplifier 220-2 reads the bit stored in the SRAM bit cell 110-1,2 by sensing the voltage difference between the bit lines BL_2 and BLB_2.

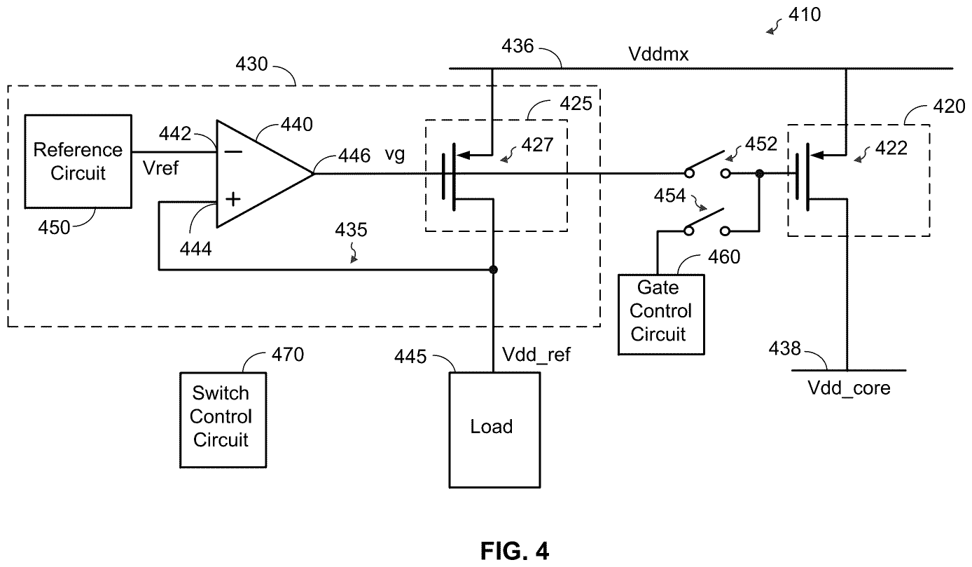

FIG. 4 shows an example of a system 410 for placing the SRAM memory in different power modes depending on use case. For example, the power modes may include an active mode, a non-retention mode, and a light-sleep mode. It is to be appreciated that the system 410 may support one or more additional power modes in some implementations.

The active mode may be used when the SRAM memory is being accessed by a processor or another circuit. The non-retention mode may be used to power collapse the SRAM memory to save power when the bits stored in the SRAM memory do not need to be retained. The light-sleep mode may be used to retain the bits stored in the SRAM memory when the SRAM memory does not need to be accessed for a period of time. During the light-sleep mode, the supply voltage of the SRAM memory is lowered to a retention voltage that is sufficient to retain the bit stored in the SRAM memory. The lower voltage of the retention voltage reduces leakage current in the SRAM memory to conserve power.

In this example, the system 410 includes a first switch 420 coupled between a first supply rail 436 and a second supply rail 438. The first supply rail 436 provides a supply voltage Vddmx, and the second supply rail 438 may be coupled to SRAM bit cells (e.g., the SRAM bit cells 110-2,1 and 110-2,2) in the memory array 310. The first switch 420 may be used to selectively couple the second supply rail 438 to the first supply rail 436 to support the active mode and the non-retention mode. The first switch 420 may also be used to set the voltage Vdd_core at the second supply rail 438 to the retention voltage in the light-sleep mode, as discussed further below. In some implementations, the first switch 420 (e.g., a first switch transistor 422) may include multiple switches (e.g., multiple switch transistors) distributed between the first supply rail 436 and the second supply rail 438.

In the example shown in FIG. 4, the first switch 420 includes a first switch transistor 422 coupled between the first supply rail 436 and the second supply rail 438. The first switch transistor 422 may be implemented with a PFET, in which the source of the first switch transistor 422 is coupled to the first supply rail 436 and the drain of the first switch transistor 422 is coupled to the second supply rail 438, as shown in FIG. 4. In some implementations, the first switch transistor 422 may include multiple transistors distributed between the first supply rail 436 and the second supply rail 438.

The system 410 also includes a voltage regulator 430 configured to generate a gate voltage vg that causes the first switch transistor 422 to set the voltage Vdd_core of the second supply rail 438 at the retention voltage in the light-sleep mode, as discussed further below. The voltage regulator 430 includes a second switch 425, an amplifier 440, and a reference circuit 450. The second switch 425 is coupled between the first supply rail 436 and a load 445. As discussed further below, in certain aspects, the load 445 includes dummy SRAM bit cells (not shown in FIG. 4) which may be arranged in a column.

A dummy SRAM bit cell is an SRAM bit cell that is used to act as a load for the voltage regulator 430 and is not used for bit storage. The dummy SRAM bit cell may have the same structure or substantially the same structure as an SRAM bit cell used for data storage such that the load of the dummy SRAM bit cell approximates the load (e.g., capacitive load) of the SRAM bit cell used for data storage.

In the example shown in FIG. 4, the second switch 425 includes a second switch transistor 427 coupled between the first supply rail 436 and the load 445. The second switch transistor 427 may be implemented with a PFET, in which the source of the second switch transistor 427 is coupled to the first supply rail 436 and the drain of the second switch transistor 427 is coupled to the load 445. In some implementations, the second switch transistor 427 may include multiple transistors coupled in parallel.

The amplifier 440 has a first input 442 (e.g., a minus input), a second input 444 (e.g., a plus input), and an output 446. The first input 442 is coupled to the reference circuit 450. The reference circuit 450 is configured to generate a reference voltage Vref and output the reference voltage Vref to the first input 442 of the amplifier 440. The reference circuit 450 may be implemented with a voltage divider, a digital-to-analog converter, etc. The second input 444 (e.g., a plus input) is coupled to the load 445 (e.g., dummy SRAM bit cells) via a feedback path 435. The output 446 is coupled to the gate of the second switch transistor 427.

During operation, the amplifier 440 senses the voltage Vdd_ref on the load 445 and generates the gate voltage vg at the output 446 based on the difference between the sensed voltage Vdd_ref and the reference voltage Vref. The amplifier 440 outputs the gate voltage vg to the gate of the second switch transistor 427 to drive the gate of the second switch transistor 427. The feedback path 435, the amplifier 440, and the second switch transistor 427 form a feedback loop that causes the amplifier 440 to drive the gate of the second switch transistor 427 in a direction that reduces the difference between the voltage Vdd_ref on the load 445 and the reference voltage Vref. As a result, the feedback loop forces the voltage Vdd_ref on the load 445 to be approximately equal to the reference voltage Vref. In certain aspects, the reference circuit 450 sets the reference voltage Vref at the retention voltage for the light-sleep mode, which causes the feedback loop to set the voltage Vdd_ref on the load 445 at the retention voltage. In this example, the load 445 may also be referred to as a sense load since the amplifier 440 senses the voltage Vdd_ref on the load 445.

The system 410 also includes a first gate switch 452, a second gate switch 454, a gate control circuit 460, and a switch control circuit 470. The first gate switch 452 is coupled between the gate of the first switch transistor 422 and the output 446 of the amplifier 440. The second gate switch 454 is coupled between the gate of the first switch transistor 422 and the gate control circuit 460. Each of the gate switches 452 and 454 may be implemented with a transistor, a transmission gate, etc. The on/off states of the gate switches 452 and 454 are controlled by the switch control circuit 470. For ease of illustration, the individual connections between the switch control circuit 470 and the gate switches 452 and 454 are not shown in FIG. 4.

In certain aspects, the switch control circuit 470 is configured to control the on/off states of the gate switches 452 and 454 depending on the desired power mode. For example, the switch control circuit 470 may open the first gate switch 452 and close the second gate switch 454 in the active mode or the non-retention mode. In this case, the gate of the first switch transistor 422 is coupled to the gate control circuit 460. For the active mode, the gate control circuit 460 may fully turn on the first switch transistor 422 by pulling the gate of the first switch transistor 422 low (e.g., coupling the gate of the first switch transistor 422 to ground). This causes the voltage Vdd_core at the second supply rail 438 to be approximately equal to Vddmx (assuming a very low IR drop across the first switch transistor 422). For the non-retention mode, the gate control circuit 460 may pull the gate of the first switch transistor 422 high (e.g., couple the gate of the first switch transistor 422 to Vddmx or another high voltage) to turn off the first switch transistor 422. This power collapses the memory array 310 (shown in FIGS. 3A and 3B) to save power when the bits in the memory array 310 do not need to be retained.

The switch control circuit 470 may close the first gate switch 452 and open the second gate switch 454 in the light-sleep mode. In this case, the output 446 of the amplifier 440 is coupled to the gate of the first switch transistor 422 through the first gate switch 452. As a result, the gate voltage vg drives the gate of the first switch transistor 422 in the light-sleep mode. The gate voltage vg (which is set by the feedback loop of the voltage regulator 430) causes the first switch transistor 422 to maintain the voltage Vdd_core at the second supply rail 438 at approximately the retention voltage. The retention voltage is sufficient to retain the bits in the SRAM memory and is lower than the supply voltage Vddmx in the active mode to reduce leakage current in the light-sleep mode. The retained bits may be accessed later when the SRAM memory is placed back in the active mode.

As discussed above, the load 445 used by the voltage regulator 430 to set the gate voltage vg may include dummy SRAM bit cells that approximately replicate the load of SRAM bit cells used for data storage (also referred to as regular SRAM bit cells). It is desirable to place the dummy SRAM bit cells in the same memory array as the regular SRAM bit cells to improve area efficiency by eliminating the need for a separate array and edge cells for the dummy SRAM bit cells.

A challenge with placing dummy SRAM bit cells in the same memory array as regular SRAM bit cells is that the dummy SRAM bit cells need isolation from the word lines used in the array for the regulator SRAM bit cells. However, in existing memory arrays, each word line in the array runs across the entire respective row with no break in the word line to support word line isolation between two adjacent bit cells in the row.

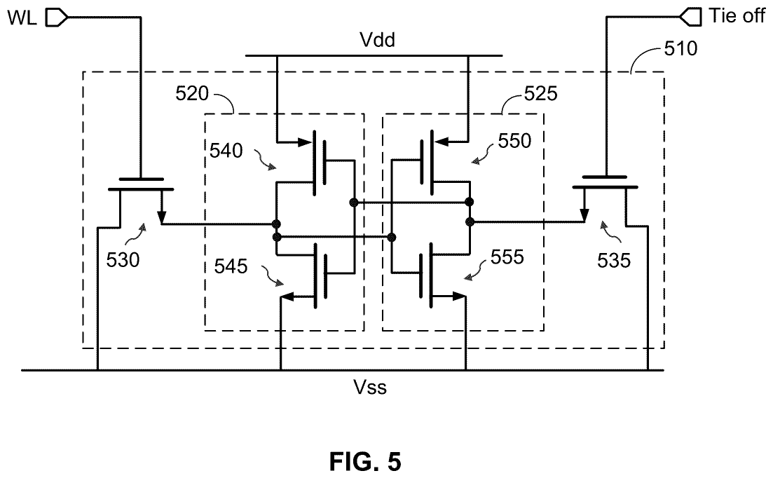

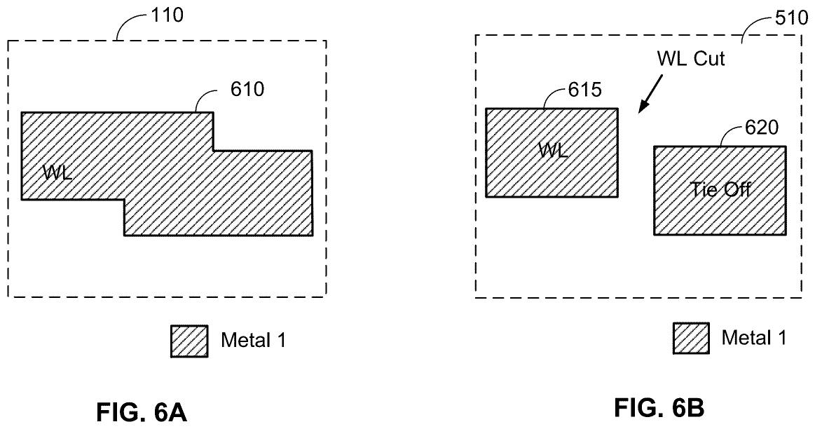

To address the above, aspects of the present disclosure provide a novel word line (WL) cut bit cell that cuts (i.e., breaks) a word line in a memory array to facilitate word line isolation. In this regard, FIGS. 5, 6A, and 6B show an example of a WL cut bit cell 510 according to certain aspects of the present disclosure.

In this example, the WL cut bit cell 510 includes a first inverter 520, a second inverter 525, a first pass transistor 530, and a second pass transistor 535. The first inverter 520, the second inverter 525, the first pass transistor 530, and the second pass transistor 535 may be the same or substantially the same as the first inverter 120, the second inverter 125, the first pass transistor 130, and the second pass transistor 135, respectively, of the SRAM bit cell 110 shown in FIGS. 1A and 1B. For example, the first inverter 520, the second inverter 525, the first pass transistor 530, and the second pass transistor 535 may be fabricated on the chip using the same process steps used to fabricate the first inverter 120, the second inverter 125, the first pass transistor 130, and the second pass transistor 135, respectively. As discussed further below, the WL cut bit cell 510 may be used as a dummy SRAM bit cell for the load 445 of the voltage regulator 430.

In this example, the second inverter 525 is cross coupled with the first inverter 520, in which the output of the first inverter 520 is coupled to the input of the second inverter 525 and the output of the second inverter 525 is coupled to the input of the first inverter 520. In the example shown in FIG. 5, the first inverter 520 includes a PFET 540 and an NFET 545 in which the source of the PFET 540 is coupled to a supply rail, the gates of the PFET 540 and the NFET 545 are coupled to the input of the first inverter 520, the drains of the PFET 540 and the NFET 545 are coupled to the output of the first inverter 520, and the source of the NFET 545 is coupled to the low rail (e.g., ground rail). The second inverter 525 includes a PFET 550 and an NFET 555 in which the source of the PFET 550 is coupled to the supply rail, the gates of the PFET 550 and the NFET 555 are coupled to the input of the second inverter 525, the drains of the PFET 550 and the NFET 555 are coupled to the output of the second inverter 525, and the source of the NFET 555 is coupled to the low rail (e.g., ground rail).

The first pass transistor 530 is coupled between the output of the first inverter 520 and the low rail (e.g., a ground rail), and the second pass transistor 535 is coupled between the output of the second inverter 525 and the low rail (e.g., a ground rail). This is because the WL cut bit cell 510 is not used for data storage and therefore does not need to be accessed for write/read operations via bit lines. The gate of the first pass transistor 530 is coupled to a word line WL and the gate of the second pass transistor 535 is tied off. For example, the gate of the second pass transistor 535 may be tied low, as discussed further below. As used herein, “tied low” means tied to a low potential (e.g., ground potential), where the low potential is the potential of a low rail (e.g., the ground rail).

In this example, the word line WL is cut between the first pass transistor 530 and the second pass transistor 535. For example, the word line WL may be formed in a metal layer (e.g., metal layer M1) of the chip in which the metal of the word line WL is cut (e.g., using an etching process). In this regard, FIG. 6A shows a top view of an exemplary layout of the word line WL 610 over the SRAM bit cell 110. In this example, the word line WL 610 is formed in metal layer M1 and extends above the gate of the first pass transistor 130 and the gate of the second pass transistor 135 (shown in FIGS. 1A and 1B). The bit lines BL and BLB may be formed in metal layer M0 (not shown in FIG. 6A), which is below metal layer M1.

FIG. 6B shows an example in which the word line WL 610 is placed over the WL cut bit cell 510 (shown in FIG. 5) and cut into a first portion 615 and a second portion 620. In this example, the first portion 615 extends above the gate of the first pass transistor 530 (shown in FIG. 5) and the second portion 620 extends above the gate of the second pass transistor 535 (shown in FIG. 5). The first portion 615 couples the gate of the first pass transistor 530 to the word line WL and the second portion 620 is used to tie off the gate of the second pass transistor 535 (e.g., to ground potential). Thus, in this example, the layout of the word line WL 610 used for the SRAM bit cell 110 may also be used for the WL cut bit cell 510 by cutting the word line WL 610 into the first portion 615 and the second portion 620.

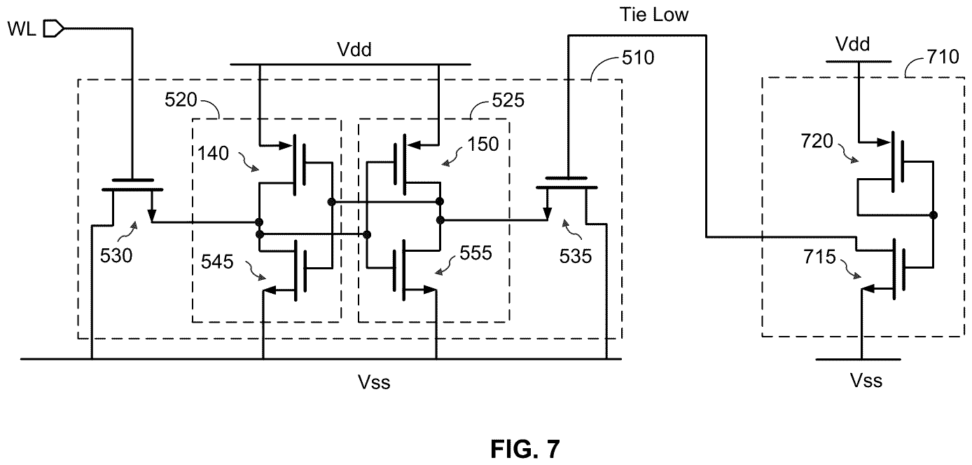

FIG. 7 shows an example in which the gate of the second pass transistor 535 is tied low using a tie-low cell 710. The tie-low cell 710 is configured to couple the gate of the second pass transistor 535 to the low rail (e.g., ground rail). Tie-low cells are known in the art for coupling the gate of a transistor to a low rail while protecting the gate oxide of the transistor from large disturbances on the low rail.

In the example in FIG. 7, the tie-low cell 710 includes a PFET 720 and an NFET 715. The source of the PFET 720 is coupled to the supply rail and the drain and the gate of the PFET 720 are coupled together. The drain of the NFET 715 is coupled to the gate of the second pass transistor 535, the gate of the NFET 715 is coupled to the drain and the gate of the PFET 720, and the source of the gate of the NFET 715 is coupled to the low rail. When the supply rail provides a supply voltage at the source of the PFET 720, the PFET 720 turns on the NFET 715. This causes the NFET 715 to couple the gate of the second pass transistor 535 to the low rail through the NFET 715. It is to be appreciated that the supply voltage provided to the tie-low cell 710 may be the same or different from the supply voltage provided to the WL cut bit cell 510. It is to be appreciated that the present disclosure is not limited to the exemplary tie-low cell 710 shown in FIG. 7 and that the gate of the second pass transistor 535 may be coupled to the low rail using another type of tie-low cell.

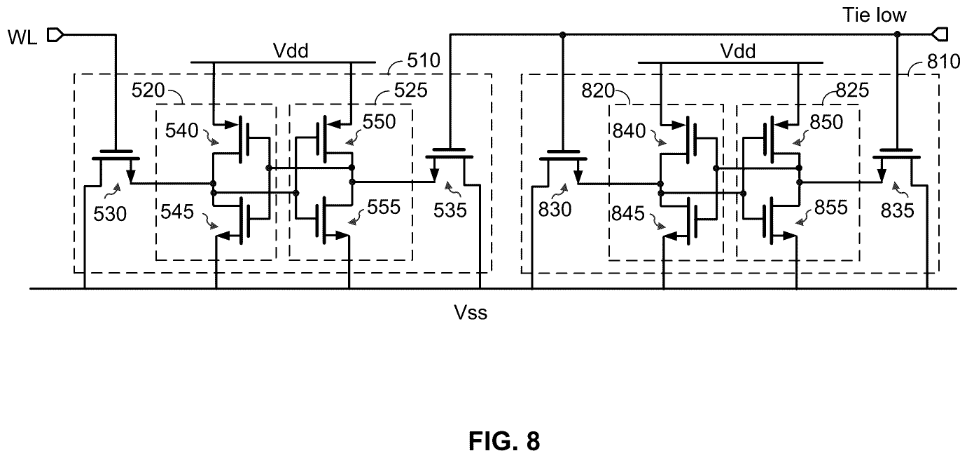

FIG. 8 shows an example of a tied-off bit cell 810 that is adjacent to the WL cut bit cell 510. In this example, the WL cut bit cell 510 isolates the tied-off bit cell 810 from the word line WL. As discussed further below, the tied-off bit cell 810 may be used as a dummy SRAM bit cell for the load 445 of the voltage regulator 430 (shown in FIG. 4). In certain aspects, the tied-off bit cell 810 may be implemented with an SRAM bit cell with the pass transistors of the SRAM bit cell coupled to the low rail (e.g., ground rail).

In the example in FIG. 8, the tied-off bit cell 810 includes a first inverter 820, a second inverter 825, a first pass transistor 830, and a second pass transistor 835. The first inverter 820, the second inverter 825, the first pass transistor 830, and the second pass transistor 835 may be the same or substantially the same as the first inverter 120, the second inverter 125, the first pass transistor 130, and the second pass transistor 135, respectively, of the SRAM bit cell 110 shown in FIGS. 1A and 1B. For example, the first inverter 820, the second inverter 825, the first pass transistor 830, and the second pass transistor 835 may be fabricated on the chip using the same process steps used to fabricate the first inverter 120, the second inverter 125, the first pass transistor 130, and the second pass transistor 135, respectively.

In this example, the second inverter 825 is cross coupled with the first inverter 820, in which the output of the first inverter 820 is coupled to the input of the second inverter 825 and the output of the second inverter 825 is coupled to the input of the first inverter 820. In the example shown in FIG. 8, the first inverter 820 includes a PFET 840 and an NFET 845 in which the source of the PFET 840 is coupled to a supply rail, the gates of the PFET 840 and the NFET 845 are coupled to the input of the first inverter 820, the drains of the PFET 840 and the NFET 845 are coupled to the output of the first inverter 820, and the source of the NFET 845 is coupled to the low rail (e.g., ground rail). The second inverter 825 includes a PFET 850 and an NFET 855 in which the source of the PFET 850 is coupled to the supply rail, the gates of the PFET 850 and the NFET 855 are coupled to the input of the second inverter 825, the drains of the PFET 850 and the NFET 855 are coupled to the output of the second inverter 825, and the source of the NFET 855 is coupled to the low rail (e.g., ground rail).

The first pass transistor 830 is coupled between the output of first inverter 820 and low rail and the second pass transistor 835 is coupled between the output of the second inverter 825 and the low rail. In this example, the gate of the first pass transistor 830 and the gate of the second pass transistor 835 are tied low. In the example shown in FIG. 8, the gate of the first pass transistor 830 and the gate of the second pass transistor 835 are coupled to the gate of the second pass transistor 535 in the WL cut bit cell 510, which is also tied low in this example. For example, the gate of the first pass transistor 830, the gate of the second pass transistor 835, and the gate of the second pass transistor 535 may all be coupled to the low rail through the tie-low cell 710 (shown in FIG. 7), in which the drain of the NFET 715 is coupled to the gate of the first pass transistor 830, the gate of the second pass transistor 835, and the gate of the second pass transistor 535.

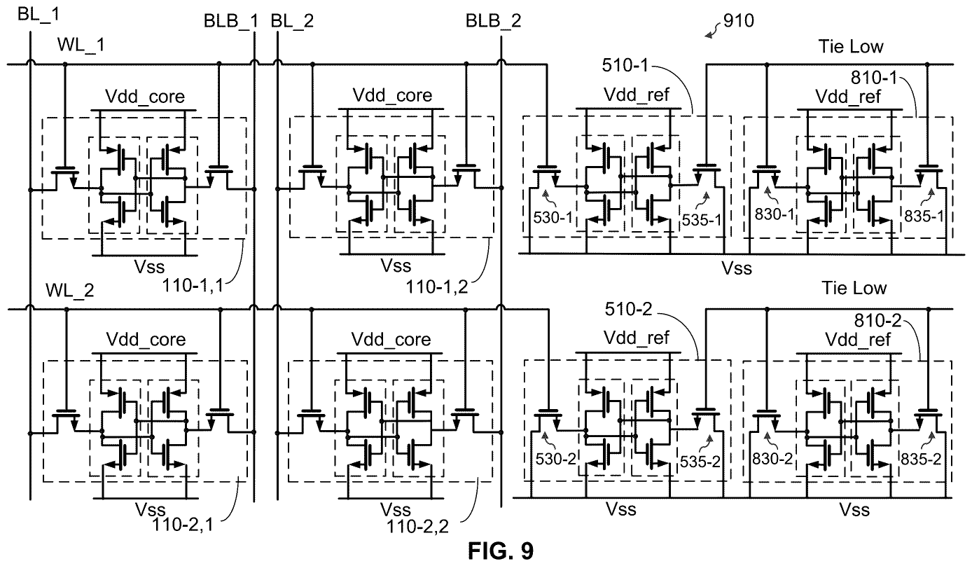

FIG. 9 shows an example of a memory array 910 including regulator SRAM bit cells for data storage and WL cut bit cells according to certain aspects. In the example in FIG. 9, the regular SRAM bit cells include the SRAM bit cells 110-1,1 and 110-1,2 in the first row and the SRAM bit cells 110-2,1 and 110-2,2 in the second row discussed above with reference to FIGS. 3A and 3B. As discussed above, the bit lines BL_1 and BLB_1 are coupled to the SRAM bit cells 110-1,1 and 110-2,1 in the first column, and the bit lines BL_2 and BLB_2 are coupled to the SRAM bit cells 110-1,2 and 110-2,2 in the second column.

The WL cut bit cells include a first WL cut bit cell 510-1 in the first row and a second WL cut bit cell 510-2 in the second row. Each of the WL cut bit cell 510-1 and 510-2 may be a separate instance (i.e., copy) of the WL cut bit cell 510. Thus, the description of the WL cut bit cell 510 given above applies to each of the WL cut bit cells 510-1 and 510-2. In this example, the WL cut bit cells 510-1 and 510-2 are arranged in a third column adjacent to the second column.

In this example, the first word line WL_1 is cut between the pass transistors 530-1 and 535-1 of the first WL cut bit cell 510-1. The first word line WL_1 is coupled to the gate of the first pass transistor 530-1 of the first WL cut bit cell 510-1 and the gate of the second pass transistor 535-1 of the first WL cut bit cell 510-1 is tied low. For example, the gate of the second pass transistor 535-1 may be coupled to a respective instance of the tie-low cell 710 shown in FIG. 7 to tie the gate of the second pass transistor 535-1 low. The first pass transistor 530-1 and the second pass transistor 535-1 are coupled to the low rail, as shown in FIG. 9.

In this example, the second word line WL_2 is cut between the pass transistors 530-2 and 535-2 of the second WL cut bit cell 510-2. The second word line WL_2 is coupled to the gate of the first pass transistor 530-2 of the second WL cut bit cell 510-2 and the gate of the second pass transistor 535-2 of the second WL cut bit cell 510-2 is tied low. For example, the gate of the second pass transistor 535-2 may be coupled to a respective instance of the tie-low cell 710 shown in FIG. 7 to tie the gate of the second pass transistor 535-2 low. The first pass transistor 530-2 and the second pass transistor 535-2 are coupled to the low rail, as shown in FIG. 9.

In the example shown in FIG. 9, the memory array 910 also include a first tied-off bit cell 810-1 in the first row and a second tied-off bit cell 810-2 in the second row. Each of the tied-off bit cells 810-1 and 810-2 may be a separate instance (i.e., copy) of the tied-off bit cell 810. Thus, the description of the tied-off bit cell 810 given above applies to each of the tied-off bit cell 810. In this example, the tied-off bit cells 810-1 and 810-2 are arranged in a fourth column adjacent to the third column.

In this example, the first tied-off bit cell 810-1 is adjacent to the first WL cut bit cell 510-1 in which the gates of the pass transistors 830-1 and 835-1 of the first tied-off bit cell 810-1 are coupled to the gate of the second pass transistor 535-1 of the first WL cut bit cell 510-1. The gates of the pass transistors 830-1, 835-1, and 535-1 are tied low (e.g., by coupling the gates of the pass transistors 830-1, 835-1, and 535-1 to a respective instance of the tie-low cell 710).

In this example, the second tied-off bit cell 810-2 is adjacent to the second WL cut bit cell 510-2 in which the gates of the pass transistors 830-2 and 835-2 of the second tied-off bit cell 810-2 are coupled to the gate of the second pass transistor 535-2 of the second WL cut bit cell 510-2. The gates of the pass transistors 830-2, 835-2, and 535-2 are tied low (e.g., by coupling the gates of the pass transistors 830-2, 835-2, and 535-2 to a respective instance of the tie-low cell 710).

In this example, the cross-coupled inverters of the SRAM bit cells 110-1,1 to 110-2,2 may be coupled to the second supply rail 438 to receive the supply voltage Vdd_core shown in FIG. 4. This allows the system 410 to selectively place the SRAM bit cells 110-1,1 to 110-2,2 in the active mode, the non-retention mode, or the light-sleep mode, as discussed above with reference to FIG. 4. In certain aspects, the switch 420 may include multiple switches distributed between the first supply rail 436 and the second supply rail 438.

In this example, the cross-coupled inverters of the WL cut bit cells 510-1 and 510-2 are coupled to the voltage regulator 430 to provide dummy SRAM bit cells for the load 445. The cross-coupled inverters of the tied-off bit cells 810-1 and 810-2 may also be coupled to the voltage regulator 430 to provide additional dummy SRAM bit cells for the load 445. Thus, in this example, the load 445 may include the WL cut bit cells 510-1 to 510-2 and the tied-off bit cells 810-1 and 810-2. As shown in FIG. 9, the voltage on the load 445 is Vdd_ref, which is sensed by the voltage regulator 430, as discussed above with reference to FIG. 4. It is to be appreciated that the present disclosure is not limited to this example. For example, the tied-off bit cells 810-1 and 810-2 may be omitted in some implementations.

In this example, the WL cut bit cells 510-1 and 510-2 cut the word lines WL_1 and WL_2, respectively, which provide word line isolation for the placement of dummy SRAM bit cells (e.g., the WL cut bit cells 510-1 and 510-2 and the tie-off bit cells 810-1 and 810-2) in the memory array 910. Placing the dummy SRAM bit cells in the memory array 910 improves area efficiency by eliminating the need for a separate array and edge cells for the dummy SRAM bit cells. In addition, the dummy SRAM bit cells are subject to substantially the same temperature and process as the regular SRAM bit cells in the array 910. As a result, the load of the dummy SRAM bit cells tracks variations in the load of the regular SRAM bit cells caused by temperature and process variations.

In this example, the row decoder 350 (shown in FIG. 3B) may be coupled to the word lines WL_1 and WL_2 to select the SRAM bit cells 110-1,1 and 110-1,2 in the first row or the SRAM bit cells 110-2,1 and 110-2,2 in the second row, as discussed above. For example, to select the first row, the row decoder 350 may set the word line WL_1 high. In this case, the pass transistors 130-1,1, 135-1,1, 130-1,2 and 135-1,2 in the SRAM bit cells 110-1,1 and 110-1,2 turn on to provide access to the SRAM bit cells 110-1,1 and 110-1,2 for a write operation and/or a read operation via the bit lines BL_1, BLB_1, BL_2, and BLB_2, as discussed above. Not that the reference numbers for the pass transistors 130-1,1, 135-1,1, 130-1,2 and 135-1,2 are not shown in FIG. 9 for ease of illustration. The gate of the second pass transistor 535-1 of the first WL cut bit cell 510-1 and the gates of the pass transistor 830-1 and 835-1 of the first tied-off bit cell 810-1 are low (e.g., ground potential) since the gates of the pass transistors 535-1, 830-1, and 835-1 are tied low, as discussed above. For a read operation, the bits in the SRAM bit cells 110-1,1 and 110-1,2 may be read using the read circuitry shown in FIG. 3B or another read circuitry.

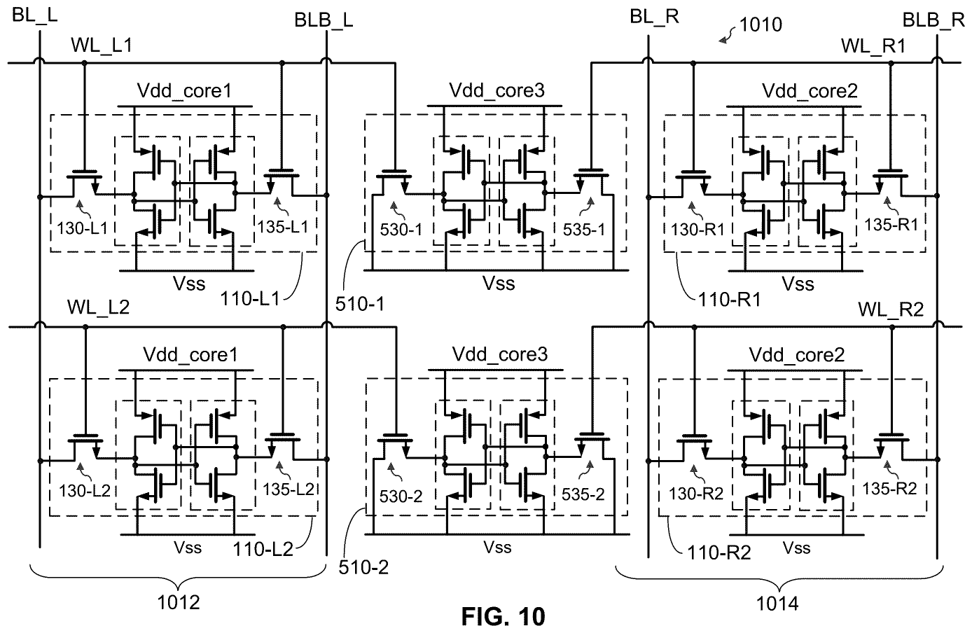

FIG. 10 shows an example in which the WL cut bit cells 510-1 and 510-2 are placed in a memory array 1010 to partition the memory array 1010 into a first portion 1012 and a second portion 1014. In the example in FIG. 10, the first portion 1012 of the array 1010 is to the left of the WL cut bit cells 510-1 and 510-2 and the second portion 1014 of the array 1010 is to the right of the WL cut bit cells 510-1 and 510-2.

The first portion 1012 of the array 1010 includes SRAM bit cell 110-L1 in the first row and SRAM bit cell 110-L2 in the second row. The SRAM bit cells 110-L1 and 110-L2 are in the same column. Although two SRAM bit cells 110-L1 and 110-L2 are shown in FIG. 10 for ease of illustration, it is to be appreciated that the first portion 1012 of the array 1010 may include additional SRAM bit cells located in the first row and the second row and additional SRAM bit cells located in additional rows and columns. The SRAM bit cell 110-L1 is coupled to word line WL_L1 and the SRAM bit cell 110-L2 is coupled to the word line WL_L2. The bit lines BL_L and BLB_L are coupled to the SRAM bit cells 110-L1 and 110-L2. In this example, the rows in the first portion 1012 of the array 1010 may be selected for read/write operations using a first row decoder (e.g., a first instance of the row decoder 350) coupled to the word lines WL_L1 and WL_L2.

The second portion 1014 of the array 1010 includes SRAM bit cell 110-R1 in the first row and SRAM bit cell 110-R2 in the second row. The SRAM bit cells 110-R1 and 110-R2 are in the same column. Although two SRAM bit cells 110-R1 and 110-R2 are shown in FIG. 10 for ease of illustration, it is to be appreciated that the second portion 1014 of the array 1010 may include additional SRAM bit cells located in the first row and the second row and additional SRAM bit cells located in additional rows and columns. The SRAM bit cell 110-R1 is coupled to word line WL_R1 and the SRAM bit cell 110-R2 is coupled to the word line WL_R2. The bit lines BL_R and BLB_R are coupled to the SRAM bit cells 110-R1 and 110-R2. In this example, the rows in the second portion 1014 of the array 1010 may be selected for read/write operations using a second row decoder (e.g., a second instance of the row decoder 350) coupled to the word lines WL_R1 and WL_R2.

In this example, the WL cut bit cells 510-1 and 510-2 are arranged in a column between the first portion 1012 of the array 1010 and the second portion 1014 of the array 1010. The gate of the first pass transistor 530-1 of the WL cut bit cell 510-1 is coupled to the word line WL_L1 and the gate of the second pass transistor 535-1 of the WL cut bit cell 510-1 is coupled to the word line WL_R1. The gate of the first pass transistor 530-2 of the WL cut bit cell 510-2 is coupled to the word line WL_L2 and the gate of the second pass transistor 535-2 of the WL cut bit cell 510-2 is coupled to the word line WL_R2. In this example, the WL cut bit cells 510-1 and 510-2 facilitate word line separation between the first portion 1012 of the array 1010 and the second portion 1014 of the array 1010. The word line separation allows the rows in the first portion 1012 of the array 1010 and the rows in the second portion 1014 of the array 1010 to be independently selected by the respective row decoders.

In this example, the cross-coupled inverters of the SRAM bit cells 110-L1 and 110-L2 in the first portion 1012 of the array 1010 are coupled to a first supply voltage Vdd_core1, and the cross-coupled inverters of the SRAM bit cells 110-R1 and 110-R2 in the second portion 1014 of the array 1010 are coupled to a second supply voltage Vdd_core2. In certain aspects, the first supply voltage Vdd_core1 and the second supply voltage Vdd_core2 may be independently controlled by separate head switches (e.g., separate instances of the switch 420). The independent control of Vdd_core1 and Vdd_core2 allows the first portion 1012 of the array 1010 and the second portion 1014 of the array 1010 to be placed in different power modes for some use cases. It is to be appreciated that the present disclosure is not limited to this example. For example, in some implementations, the cross-coupled inverters of the SRAM bit cells 110-L1 and 110-L2 in the first portion 1012 of the array 1010 and the cross-coupled inverters of the SRAM bit cells 110-R1 and 110-R2 in the second portion 1014 of the array 1010 may be coupled to the same supply voltage.

In the example shown in FIG. 10, the cross-coupled inverters of the WL cut bit cell 510-1 to 510-2 are coupled to a third supply voltage Vdd_core3. In certain aspects, the third supply voltage Vdd_core3 may be independently controlled from the supply voltages Vdd_core1 and Vdd_core2 by a separate head switch (e.g., a separate instance of the switch 420).

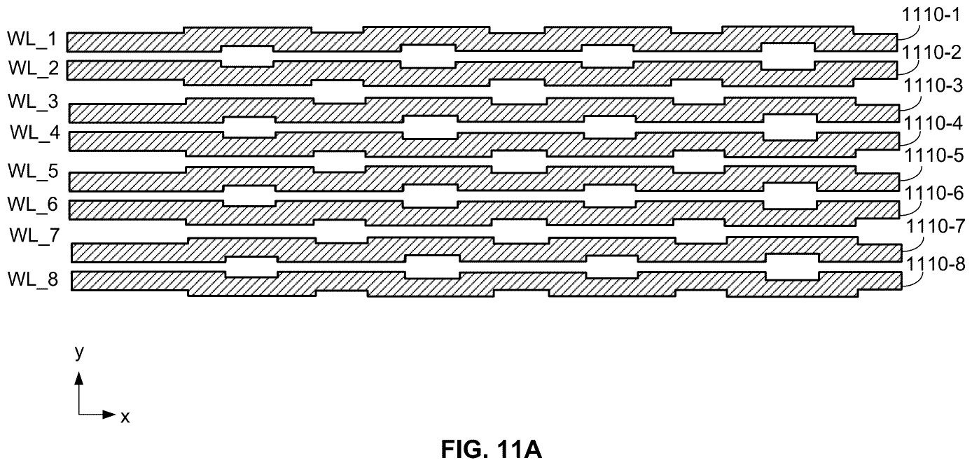

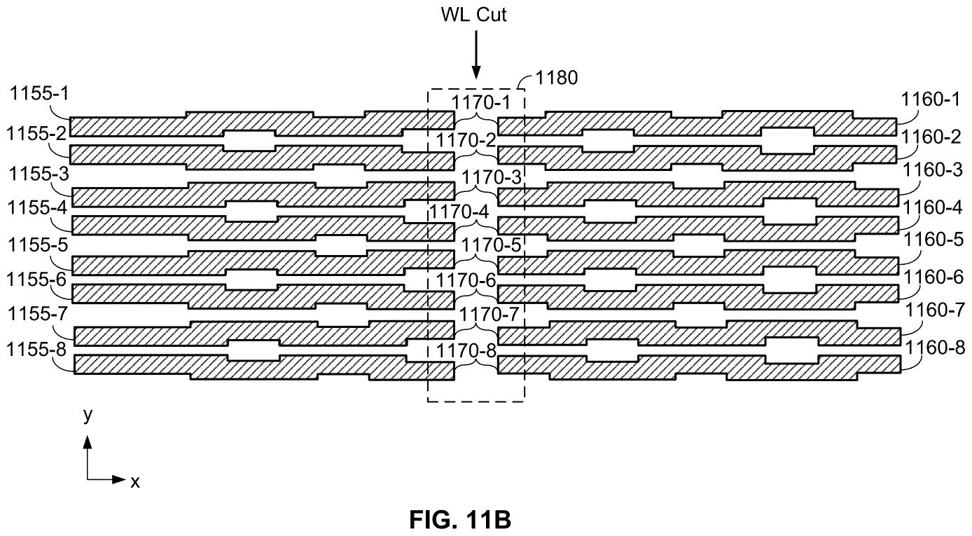

FIG. 11A shows a top view of an exemplary layout of word lines 1110-1 to 1110-8 arranged in rows according to certain aspects. Each of the word lines 1110-1 to 1110-8 extends in the x direction over a respective row of SRAM bit cells (e.g., multiple instances of the SRAM bit cell 110). Each of the word lines 1110-1 to 1110-8 is coupled to the gates of the pass transistors (e.g., pass transistors 130 and 135) of each of the SRAM bit cells in the respective row. In this example, the word lines 1110-1 to 1110-8 may be formed in metal layer M1 or another metal layer using lithographic and etching processes. The bit lines (not shown in FIG. 11A) for the SRAM bit cells may be formed in another metal layer below the word lines 1110-1 to 1110-8. It is to be appreciated that the word lines 1110-1 to 1110-8 are not limited to the exemplary shapes shown in FIG. 11A.

FIG. 11B shows an example in which the word lines 1110-1 to 1110-8 in FIG. 11A are cut in the y direction into first portions 1155-1 to 1155-8 and second portions 1160-1 to 1160-8. The first portions 1155-1 to 1155-8 and the second portions 1160-1 to 1160-8 are separated in the x direction by the word line cut, as shown in FIG. 11B. The word line cut creates gaps 1170-1 to 1170-8 separating the second portions 1160-1 to 1160-8 from the first portions 1155-1 to 1155-8, as shown in FIG. 11B. The gaps 1170-1 to 1170-8 (i.e., word line cut) are above a column of WL cut bit cells (which includes the WL cut bit cells 510-1 and 510-2 shown in FIGS. 9 and 10). This is because the word lines 1110-1 to 1110-8 that are cut to form the gaps 1170-1 to 1170-8 are formed in a metal layer located above the WL cut bit cells and the SRAM bit cells. In FIG. 11B, the area 1180 of the chip including the column of WL cut bit cells (not shown in FIG. 11B) is shown as a dashed rectangle in order to illustrate the location of the column of WL cut bit cells relative to the gaps 1170-1 to 1170-8 (i.e., word line cut).

For the memory array 910 illustrated in FIG. 9, each of the first portions 1155-1 to 1155-8 provides a respective word line for the SRAM bit cells in the respective row. For example, the first portion 1155-1 may provide the first word line WL_1 shown in FIG. 9. In this example, the first portion 1155-1 extends over the SRAM bit cells 110-1,1 and 110-1,2 and is coupled to the gates of the pass transistors of the SRAM bit cells 110-1,1 and 110-1,2 and the gate of the pass transistor 530-1 of the first WL cut bit cell 510-1. Also, in this example, the first portion 1155-2 may provide the second word line WL_2 shown in FIG. 9. In this example, the first portion 1155-2 extends over the SRAM bit cells 110-2,1 and 110-2,2 and is coupled to the gates of the pass transistors of the SRAM bit cells 110-2,1 and 110-2,2 and the pass transistor 530-2 of the second WL cut bit cell 510-2.

In this example, the second portion 1160-1 may be tied low (e.g., tied to ground) to provide a first tied-low line coupled to the gate of the pass transistor 535-1 of the first WL cut bit cell 510-1 and the gates of the pass transistors 830-1 and 835-1 of the tied-off bit cells 810-1, wherein the first tied-low line is separated from the first word line WL_1 by the gap 1170-1 above the first WL cut bit cell 510-1 (shown in FIG. 9). The second portion 1160-2 may be tied low (e.g., tied to ground) to provide a second tied-low line coupled to the gate of the pass transistor 535-2 of the second WL cut bit cell 510-2 and the gates of the pass transistors 830-2 and 835-2 of the tied-off bit cells 810-2, wherein the second tied-low line is separated from the second word line WL_2 by the gap 1170-2 above the second WL cut bit cell 510-2 (shown in FIG. 9). In this example, the word line cut extends in the y direction between the pass transistors 530-1 and 535-1 of the first WL cut bit cell 510-1 and between the pass transistors 530-2 and 535-2 of the second WL cut bit cell 510-2.

For the memory array 1010 illustrated in FIG. 10, each of the first portions 1155-1 to 1155-8 provides a respective word line for the SRAM bit cells in the respective row in the first portion 1012 of the array 1010. For example, the first portion 1155-1 and the first portion 1155-2 may provide the word lines WL_L1 and WL_2, respectively, shown in FIG. 10. In this example, the first portion 1155-1 (i.e., word line WL_L1 in this example) is coupled to the gates of the pass transistors 130-L1 and 135-L1 of the SRAM bit cell 110-L1 in the first row and the gate of the pass transistor 530-1 of the first WL cut bit cell 510-1 (shown in FIG. 10). The first portion 1155-2 (i.e., word line WL_L2 in this example) is coupled to the gates of the pass transistors 130-L2 and 135-L2 of the SRAM bit cell 110-L2 in the second row and the gate of the pass transistor 530-2 of the second WL cut bit cell 510-2 (shown in FIG. 10).

Also, in this example, each of the second portions 1160-1 to 1160-8 provides a respective word line for the SRAM bit cells in the respective row in the second portion 1014 of the array 1010. For example, the second portion 1160-1 and the second portion 1160-2 may provide the word lines WL_R1 and WR_2, respectively, shown in FIG. 10. In this example, the second portion 1160-1 (i.e., word line WL_R1 in this example) is coupled to the gates of the pass transistors 130-R1 and 135-R1 of the SRAM bit cell 110-R1 in the first row and the gate of the pass transistor 535-1 of the first WL cut bit cell 510-1 (shown in FIG. 10). The gap 1170-1 separating the first portion 1155-1 (i.e., word line WL_L1 in this example) and the second portion 1160-1 (i.e., word line WL_R1 in this example) is above the first WL cut bit cell 510-1 (shown in FIG. 10). Also, in this example, the second portion 1160-2 (i.e., word line WL_R2 in this example) is coupled to the gates of the pass transistors 130-R2 and 135-R2 of the SRAM bit cell 110-R2 in the second row and the gate of the pass transistor 535-2 of the second WL cut bit cell 510-2 (shown in FIG. 10). The gap 1170-2 separating the first portion 1155-2 (i.e., word line WL_L2 in this example) and the second portion 1160-2 (i.e., word line WL_R2 in this example) is above the second WL cut bit cell 510-2 (shown in FIG. 10).

Implementation examples are described in the following numbered clauses:
1. A system, comprising:
   a first static-random access memory (SRAM) bit cell coupled to a first word line; and
   a first word line (WL) cut bit cell, wherein the first WL cut bit cell comprises:
      a first inverter;
      a second inverter cross-coupled with the first inverter;
      a first pass transistor coupled between an output of the first inverter and a low rail, wherein a gate of the first pass transistor is coupled to the first word line; and
      a second pass transistor coupled between an output of the second inverter and the low rail, wherein a gate of the second pass transistor is tied low.
2. The system of clause 1, wherein the first word line is cut between the first pass transistor and the second pass transistor.
3. The system of clause 1 or 2, further comprising a tie-low cell coupled to the gate of the second pass transistor.
4. The system of clause 3, wherein the tie-low cell comprises:
   a p-type field effect transistor (PFET), wherein a source of the PFET is coupled to a supply rail, and a gate and a drain of the PFET are coupled together; and
   an n-type field effect transistor (NFET), wherein a gate of the NFET is coupled to the gate of the PFET, a source of the NFET is coupled to the low rail, and a drain of the NFET is coupled to the gate of the second pass transistor.
5. The system of any one of clauses 1 to 4, wherein the low rail comprises a ground rail.
6. The system of any one of clauses 1 to 5, wherein tied low is tied to a ground.
7. The system of any one of clauses 1 to 6, wherein the first SRAM bit cell comprises:
   a third inverter;
   a fourth inverter cross-coupled with the third inverter;
   a third pass transistor coupled between an output of the third inverter and a first bit line, wherein a gate of the third pass transistor is coupled to the first word line; and
   a fourth pass transistor coupled between an output of the fourth inverter and a second bit line, wherein a gate of the fourth pass transistor is coupled to the first word line.
8. The system of clause 7, further comprising a row decoder configured to set the first word line high during a read operation of the first SRAM bit cell.
9. The system of any one of clauses 1 to 8, further comprising a tied-off bit cell, wherein the tied-off bit cell comprises:
   a third inverter;
   a fourth inverter cross-coupled with the third inverter;
   a third pass transistor coupled between an output of the third inverter and the low rail, wherein a gate of the third pass transistor is tied low; and
   a fourth pass transistor coupled between an output of the fourth inverter and the low rail, wherein a gate of the fourth pass transistor is tied low.
10. The system of clause 9, further comprising a tie-low cell coupled to the gate of the second pass transistor, the gate of the third pass transistor, and the gate of the fourth pass transistor.
11. The system of clause 10, wherein the tie-low cell comprises:
   a p-type field effect transistor (PFET), wherein a source of the PFET is coupled to a supply rail, and a gate and a drain of the PFET are coupled together; and
   an n-type field effect transistor (NFET), wherein a gate of the NFET is coupled to the gate of the PFET, a source of the NFET is coupled to the low rail, and a drain of the NFET is coupled to the gate of the second pass transistor, the gate of the third pass transistor, and the gate of the fourth pass transistor.
12. The system of any one of clauses 1 to 11, further comprising:
   a second SRAM bit cell coupled to a second word line; and
   a second WL cut bit cell, wherein the second WL cut bit cell comprises:
      a third inverter;
      a fourth inverter cross-coupled with the third inverter;
      a third pass transistor coupled between an output of the third inverter and the low rail, wherein a gate of the third pass transistor is coupled to the second word line; and
      a fourth pass transistor coupled between an output of the fourth inverter and the low rail, wherein a gate of the fourth pass transistor is tied low.
13. The system of clause 12, wherein the first word line is cut between the first pass transistor and the second pass transistor, and the second word line is cut between the third pass transistor and the fourth pass transistor.
14. The system of any one of clauses 1 to 13, further comprising:
   a first switch transistor coupled between a supply rail and the first SRAM bit cell; and
   a voltage regulator coupled to the first WL cut bit cell, wherein the voltage regulator is configured to:
sense a voltage on the first WL cut bit cell;
generate a gate voltage based on a difference between the sensed voltage and a reference voltage; and
output the gate voltage to a gate of the first switch transistor.
15. The system of clause 14, further comprising a first gate switch coupled between the voltage regulator and the gate of the first switch transistor.
16. The system of clause 15, further comprising:
   a gate control circuit; and
   a second gate switch coupled between the gate control circuit and the gate of the first switch transistor.
17. The system of clause 16, further comprising a switch control circuit configured to:
   in a first power mode, close the first gate switch and open the second gate switch; and
   in a second power mode, open the first gate switch and close the second gate switch, wherein the gate control circuit is configured to pull the gate of the first switch transistor low in the second power mode.
18. The system of clause 17, wherein the switch control circuit is configured to open the first gate switch and close the second gate switch in a third power mode, and the gate control circuit is configured to pull the gate of the first switch transistor high in the third power mode.
19. The system of any one of clauses 14 to 18, wherein the voltage regulator comprises:
   a second switch transistor coupled between the supply rail and the first WL cut bit cell; and
   an amplifier having a first input, a second input, and an output, wherein the first input of the amplifier is configured to receive the reference voltage, the second input of the amplifier is coupled between the second switch transistor and the first WL cut bit cell, and the output of the amplifier is coupled to a gate of the second switch transistor.
20. The system of clause 19, further comprising a first gate switch coupled between the output of the amplifier and the gate of the first switch transistor.
21. The system of clause 20, further comprising:
   a gate control circuit; and
   a second gate switch coupled between the gate control circuit and the gate of the first switch transistor.
22. The system of clause 21, further comprising a switch control circuit configured to:
   in a first power mode, close the first gate switch and open the second gate switch; and
   in a second power mode, open the first gate switch and close the second gate switch, wherein the gate control circuit is configured to pull the gate of the first switch transistor low in the second power mode.
23. A system, comprising:
   a first static-random access memory (SRAM) bit cell coupled to a first word line;
   a second SRAM bit cell coupled to a second word line; and
   a first word line (WL) cut bit cell, wherein the first WL cut bit cell comprises:
      a first inverter;
      a second inverter cross-coupled with the first inverter;
   a first pass transistor coupled between an output of the first inverter and a low rail, wherein a gate of the first pass transistor is coupled to the first word line; and
   a second pass transistor coupled between an output of the second inverter and the low rail, wherein a gate of the second pass transistor is coupled to the second word line.
24. The system of clause 23, wherein the first SRAM bit cell comprises:
   a third inverter;
   a fourth inverter cross-coupled with the third inverter;
   a third pass transistor coupled between an output of the third inverter and a first bit line, wherein a gate of the third pass transistor is coupled to the first word line; and
   a fourth pass transistor coupled between an output of the fourth inverter and a second bit line, wherein a gate of the fourth pass transistor is coupled to the first word line.
25. The system of clause 24, wherein the second SRAM bit cell comprises:
   a fifth inverter;
   a sixth inverter cross-coupled with the fifth inverter;
   a fifth pass transistor coupled between an output of the fifth inverter and a third bit line, wherein a gate of the fifth pass transistor is coupled to the second word line; and
   a sixth pass transistor coupled between an output of the sixth inverter and a fourth bit line, wherein a gate of the sixth pass transistor is coupled to the second word line.
26. A system, comprising:
   first static-random access memory (SRAM) bit cells arranged in a first row;
   a first word line (WL) cut bit cell in the first row;
   a first word line extending over the first SRAM bit cells, wherein the first word line is coupled to each of the first SRAM bit cells, and the first word line is cut above the first WL cut bit cell;
   second SRAM bit cells arranged in a second row;
   a second WL cut bit cell in the second row; and
   a second word line extending over the second SRAM bit cells, wherein the second word line is coupled to each of the second SRAM bit cells, and the second word line is cut above the second WL cut bit cell.
27. The system of clause 26, further comprising:
   a first tied-low line coupled to the first WL cut bit cell, wherein the first tied-low line is tied low and extends in a same direction as the first word line; and
   a second tied-low line coupled to the second WL cut bit cell, wherein the second tied-low line is tied low and extends in a same direction as the second word line.
28. The system of clause 27, wherein tied low is tied to a ground.
29. The system of clause 27 or 28, wherein the first tied-low line is separated from the first word line by a first gap above the first WL cut bit cell, and the second tied-low line is separated from the second word line by a second gap above the second WL cut bit cell.
30. The system of any one of clauses 27 to 29, wherein the first WL cut bit cell comprises:
   a first inverter;
   a second inverter cross-coupled with the first inverter;
   a first pass transistor coupled between an output of the first inverter and a low rail, wherein a gate of the first pass transistor is coupled to the first word line; and
   a second pass transistor coupled between an output of the second inverter and the low rail, wherein a gate of the second pass transistor is coupled to the first tied-low line.
31. The system of clause 30, wherein the second WL cut bit cell comprises:
   a third inverter;
   a fourth inverter cross-coupled with the third inverter;
   a third pass transistor coupled between an output of the third inverter and the low rail, wherein a gate of the third pass transistor is coupled to the second word line; and
   a fourth pass transistor coupled between an output of the fourth inverter and the low rail, wherein a gate of the fourth pass transistor coupled to the second tied-low line.
32. The system of clause 30 or 31, wherein the low rail comprises a ground rail.
33. The system of clause 26, further comprising:
   third SRAM bit cells arranged in the first row;
   a third word line extending over the third SRAM bit cells, wherein the third word line is coupled to each of the third SRAM bit cells, and the third word line is cut above the first WL cut bit cell;
   fourth SRAM bit cells arranged in the second row; and
   a fourth word line extending over the fourth SRAM bit cells, wherein the fourth word line is coupled to each of the fourth SRAM bit cells, and the fourth word line is cut above the second WL cut bit cell.
34. The system of clause 33, wherein the third word line is separated from the first word line by a first gap above the first WL cut bit cell, and the fourth word line is separated from the second word line by a second gap above the second WL cut bit cell.
35. The system of clause 33 or 34, wherein the first WL cut bit cell comprises:
   a first inverter;
   a second inverter cross-coupled with the first inverter;
   a first pass transistor coupled between an output of the first inverter and a low rail, wherein a gate of the first pass transistor is coupled to the first word line; and
   a second pass transistor coupled between an output of the second inverter and the low rail, wherein a gate of the second pass transistor is coupled to the third word line.
36. The system of clause 35, wherein the second WL cut bit cell comprises:
   a third inverter;
   a fourth inverter cross-coupled with the third inverter;
   a third pass transistor coupled between an output of the third inverter and the low rail, wherein a gate of the third pass transistor is coupled to the second word line; and
   a fourth pass transistor coupled between an output of the fourth inverter and the low rail, wherein a gate of the fourth pass transistor coupled to the fourth word line.
37. The system of clause 35 or 36, wherein the low rail comprises a ground rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that an output may include multiple parallel outputs, and that an input may include multiple parallel inputs. As used herein, a first inverter is cross-coupled with a second inverter when the output of the first inverter is coupled to the input of the second inverter and the output of the second inverter is coupled to the input of the first inverter.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a first static-random access memory (SRAM) bit cell coupled to a first word line; and
a first word line (WL) cut bit cell, wherein the first WL cut bit cell comprises:
a first inverter;
a second inverter cross-coupled with the first inverter;
a first pass transistor coupled between an output of the first inverter and a low rail, wherein a gate of the first pass transistor is coupled to the first word line; and
a second pass transistor coupled between an output of the second inverter and the low rail, wherein a gate of the second pass transistor is tied low.

2. The system of claim 1, wherein the first word line is cut between the first pass transistor and the second pass transistor.

3. The system of claim 1, further comprising a tie-low cell coupled to the gate of the second pass transistor.

4. The system of claim 3, wherein the tie-low cell comprises:
a p-type field effect transistor (PFET), wherein a source of the PFET is coupled to a supply rail, and a gate and a drain of the PFET are coupled together; and
an n-type field effect transistor (NFET), wherein a gate of the NFET is coupled to the gate of the PFET, a source of the NFET is coupled to the low rail, and a drain of the NFET is coupled to the gate of the second pass transistor.

5. The system of claim 1, wherein the low rail comprises a ground rail.

6. The system of claim 1, wherein tied low is tied to a ground.

7. The system of claim 1, wherein the first SRAM bit cell comprises:
a third inverter;
a fourth inverter cross-coupled with the third inverter;
a third pass transistor coupled between an output of the third inverter and a first bit line, wherein a gate of the third pass transistor is coupled to the first word line; and
a fourth pass transistor coupled between an output of the fourth inverter and a second bit line, wherein a gate of the fourth pass transistor is coupled to the first word line.

8. The system of claim 7, further comprising a row decoder configured to set the first word line high during a read operation of the first SRAM bit cell.

9. The system of claim 1, further comprising a tied-off bit cell, wherein the tied-off bit cell comprises:
a third inverter;
a fourth inverter cross-coupled with the third inverter;
a third pass transistor coupled between an output of the third inverter and the low rail, wherein a gate of the third pass transistor is tied low; and
a fourth pass transistor coupled between an output of the fourth inverter and the low rail, wherein a gate of the fourth pass transistor is tied low.

10. The system of claim 9, further comprising a tie-low cell coupled to the gate of the second pass transistor, the gate of the third pass transistor, and the gate of the fourth pass transistor.

11. The system of claim 10, wherein the tie-low cell comprises:
a p-type field effect transistor (PFET), wherein a source of the PFET is coupled to a supply rail, and a gate and a drain of the PFET are coupled together; and
an n-type field effect transistor (NFET), wherein a gate of the NFET is coupled to the gate of the PFET, a source of the NFET is coupled to the low rail, and a drain of the NFET is coupled to the gate of the second pass transistor, the gate of the third pass transistor, and the gate of the fourth pass transistor.

12. The system of claim 1, further comprising:
a second SRAM bit cell coupled to a second word line; and
a second WL cut bit cell, wherein the second WL cut bit cell comprises:
a third inverter;
a fourth inverter cross-coupled with the third inverter;
a third pass transistor coupled between an output of the third inverter and the low rail, wherein a gate of the third pass transistor is coupled to the second word line; and
a fourth pass transistor coupled between an output of the fourth inverter and the low rail, wherein a gate of the fourth pass transistor is tied low.

13. The system of claim 12, wherein the first word line is cut between the first pass transistor and the second pass transistor, and the second word line is cut between the third pass transistor and the fourth pass transistor.

14. The system of claim 1, further comprising:
a first switch transistor coupled between a supply rail and the first SRAM bit cell; and
a voltage regulator coupled to the first WL cut bit cell, wherein the voltage regulator is configured to:
sense a voltage on the first WL cut bit cell;
generate a gate voltage based on a difference between the sensed voltage and a reference voltage; and
output the gate voltage to a gate of the first switch transistor.

15. The system of claim 14, further comprising a first gate switch coupled between the voltage regulator and the gate of the first switch transistor.

16. The system of claim 15, further comprising:
a gate control circuit; and
a second gate switch coupled between the gate control circuit and the gate of the first switch transistor.

17. The system of claim 16, further comprising a switch control circuit configured to:
in a first power mode, close the first gate switch and open the second gate switch; and
in a second power mode, open the first gate switch and close the second gate switch, wherein the gate control circuit is configured to pull the gate of the first switch transistor low in the second power mode.

18. The system of claim 17, wherein the switch control circuit is configured to open the first gate switch and close the second gate switch in a third power mode, and the gate control circuit is configured to pull the gate of the first switch transistor high in the third power mode.

19. The system of claim 14, wherein the voltage regulator comprises:
a second switch transistor coupled between the supply rail and the first WL cut bit cell; and
an amplifier having a first input, a second input, and an output, wherein the first input of the amplifier is configured to receive the reference voltage, the second input of the amplifier is coupled between the second switch transistor and the first WL cut bit cell, and the output of the amplifier is coupled to a gate of the second switch transistor.

20. The system of claim 19, further comprising a first gate switch coupled between the output of the amplifier and the gate of the first switch transistor.

21. The system of claim 20, further comprising:
a gate control circuit; and
a second gate switch coupled between the gate control circuit and the gate of the first switch transistor.

22. The system of claim 21, further comprising a switch control circuit configured to:
in a first power mode, close the first gate switch and open the second gate switch; and
in a second power mode, open the first gate switch and close the second gate switch, wherein the gate control circuit is configured to pull the gate of the first switch transistor low in the second power mode.

23. A system, comprising:
a first static-random access memory (SRAM) bit cell coupled to a first word line;
a second SRAM bit cell coupled to a second word line; and
a first word line (WL) cut bit cell, wherein the first WL cut bit cell comprises:
a first inverter;
a second inverter cross-coupled with the first inverter;
a first pass transistor coupled between an output of the first inverter and a low rail, wherein a gate of the first pass transistor is coupled to the first word line; and
a second pass transistor coupled between an output of the second inverter and the low rail, wherein a gate of the second pass transistor is coupled to the second word line.

24. The system of claim 23, wherein the first SRAM bit cell comprises:
a third inverter;
a fourth inverter cross-coupled with the third inverter;
a third pass transistor coupled between an output of the third inverter and a first bit line, wherein a gate of the third pass transistor is coupled to the first word line; and
a fourth pass transistor coupled between an output of the fourth inverter and a second bit line, wherein a gate of the fourth pass transistor is coupled to the first word line.

25. The system of claim 24, wherein the second SRAM bit cell comprises:
a fifth inverter;
a sixth inverter cross-coupled with the fifth inverter;
a fifth pass transistor coupled between an output of the fifth inverter and a third bit line, wherein a gate of the fifth pass transistor is coupled to the second word line; and
a sixth pass transistor coupled between an output of the sixth inverter and a fourth bit line, wherein a gate of the sixth pass transistor is coupled to the second word line.

26. A system, comprising:
first static-random access memory (SRAM) bit cells arranged in a first row;
a first word line (WL) cut bit cell in the first row;
a first word line extending over the first SRAM bit cells, wherein the first word line is coupled to each of the first SRAM bit cells, and the first word line is cut above the first WL cut bit cell;
second SRAM bit cells arranged in a second row;
a second WL cut bit cell in the second row; and
a second word line extending over the second SRAM bit cells, wherein the second word line is coupled to each of the second SRAM bit cells, and the second word line is cut above the second WL cut bit cell.

27. The system of claim 26, further comprising:
a first tied-low line coupled to the first WL cut bit cell, wherein the first tied-low line is tied low and extends in a same direction as the first word line; and
a second tied-low line coupled to the second WL cut bit cell, wherein the second tied-low line is tied low and extends in a same direction as the second word line.

28. The system of claim 27, wherein tied low is tied to a ground.

29. The system of claim 27, wherein the first tied-low line is separated from the first word line by a first gap above the first WL cut bit cell, and the second tied-low line is separated from the second word line by a second gap above the second WL cut bit cell.

30. The system of claim 27, wherein the first WL cut bit cell comprises:
a first inverter;
a second inverter cross-coupled with the first inverter;
a first pass transistor coupled between an output of the first inverter and a low rail, wherein a gate of the first pass transistor is coupled to the first word line; and
a second pass transistor coupled between an output of the second inverter and the low rail, wherein a gate of the second pass transistor is coupled to the first tied-low line.

31. The system of claim 30, wherein the second WL cut bit cell comprises:
a third inverter;
a fourth inverter cross-coupled with the third inverter;
a third pass transistor coupled between an output of the third inverter and the low rail, wherein a gate of the third pass transistor is coupled to the second word line; and
a fourth pass transistor coupled between an output of the fourth inverter and the low rail, wherein a gate of the fourth pass transistor coupled to the second tied-low line.

32. The system of claim 30, wherein the low rail comprises a ground rail.

33. The system of claim 26, further comprising:
third SRAM bit cells arranged in the first row;
a third word line extending over the third SRAM bit cells, wherein the third word line is coupled to each of the third SRAM bit cells, and the third word line is cut above the first WL cut bit cell;
fourth SRAM bit cells arranged in the second row; and
a fourth word line extending over the fourth SRAM bit cells, wherein the fourth word line is coupled to each of the fourth SRAM bit cells, and the fourth word line is cut above the second WL cut bit cell.

34. The system of claim 33, wherein the third word line is separated from the first word line by a first gap above the first WL cut bit cell, and the fourth word line is separated from the second word line by a second gap above the second WL cut bit cell.

35. The system of claim 33, wherein the first WL cut bit cell comprises:
a first inverter;
a second inverter cross-coupled with the first inverter;
a first pass transistor coupled between an output of the first inverter and a low rail, wherein a gate of the first pass transistor is coupled to the first word line; and
a second pass transistor coupled between an output of the second inverter and the low rail, wherein a gate of the second pass transistor is coupled to the third word line.

36. The system of claim 35, wherein the second WL cut bit cell comprises:
a third inverter;
a fourth inverter cross-coupled with the third inverter;
a third pass transistor coupled between an output of the third inverter and the low rail, wherein a gate of the third pass transistor is coupled to the second word line; and
a fourth pass transistor coupled between an output of the fourth inverter and the low rail, wherein a gate of the fourth pass transistor coupled to the fourth word line.

37. The system of claim 35, wherein the low rail comprises a ground rail.
